(19) United States
(12) Patent Application Publication
(10) Pub. No.: US 2006/0043507 A1
(43) Pub. Date: Mar. 2, 2006

(54) Bulk acoustic wave resonator with means for suppression of pass-band ripple in bulk acoustic wave filters

(76) Inventors: Hans Lobl, Monschau-Imgenbroich (DE); Robert Milsom, Redhill Surrey (DE); Christof Metzmacher, Aachen (DE); Hans-Wolfgang Brand, Aachen (DE); Mareike Klee, Huckelhoven (DE); Rainer Kiewitt, Roetgen (DE)

Correspondence Address: PHILIPS INTELLECTUAL PROPERTY & STANDARDS, P.O. BOX 3001, BRIARCLIFF MANOR, NY, 10510, US

(21) Appl. No.: 10/527,115

(22) PCT Filed: Sep. 1, 2003
(86) PCT No.: PCT/IB03/03993

§ 371 Date: Mar. 8, 2005

(30) Foreign Application Priority Data
Sep. 12, 2002 (EP) 02256348.0

(51) Int. Cl. H01L 29/84

(52) U.S. Cl. 257/416

(57) ABSTRACT

A bulk acoustic wave resonator comprising a substrate (5), a Bragg reflector (4), a top (1) and a bottom (3) electrode and a piezoelectric layer (2) with means for suppression of the pass-band ripples in a bulk acoustic wave filter. The means for absorbing or scattering the spurious modes are a roughened rear side of the substrate (6), an absorbing layer (5) disposed on the rear side of the substrate (6) and/or an absorbing layer (5) disposed on the front side of the substrate.

The invention relates to bulk acoustic wave filters that are constructed of bulk acoustic wave (BAW) resonators which can be connected in a ladder or in a lattice type configuration. The invention especially relates to means for suppression of the bass-band ripple in bulk acoustic wave filters. BAW resonators comprise at least one first electrode, a piezoelectric layer and a second electrode. Alternatively also acoustically coupled and stacked crystal resonator configurations can be used to shape the filter curve.

To de-couple the resonator from the filter's substrate either acoustic Bragg reflectors consisting of λ/4 multi layers can be used. Alternatively the resonator can be isolated from the substrate by using an air gap or by creating a membrane structure by etching away the substrate. However, in membrane type resonator structures spurious membrane modes can be excited which can be suppressed according to U.S. 006 150 703 A by shaping the membrane in a special way (irregular shape) and by applying an absorbing layer consisting of a visco-elastic damping material around the resonator's edges to suppress lateral propagating acoustic modes.

Bragg reflectors have the advantage of having less spurious modes since mainly the longitudinal extensional mode is excited in the piezoelectric film inside the resonator. However, the reflector has to have a high reflection coefficient near 100% in the pass-band of the BAW filter to prevent the acoustic energy from penetrating into the substrate and from causing vibrations of the substrate. To get a high reflection coefficient of the reflector, as it is required for the front end use as an output or input filter, several, typically 5, pairs of layers of material having alternate high and low acoustic impedance are stacked. For the application as interference filter in the area of 1 to 10 GHz, where an extremely low insertion loss is not required, the number of pairs in the reflector could be reduced. This would save processing time and manufacturing costs. However, then more acoustic energy would pass towards the substrate and vibrations of the substrate could be seen as a strong ripple in the pass-band of a BAW filter which is composed of those BAW resonators.

It is an object of the invention to provide a bulk acoustic wave (BAW) resonator with means for suppression of pass-band ripple in BAW filters. It is another object of the invention to provide a BAW filter with an improved band-pass behavior. It is a further object to provide a method for manufacturing such a BAW resonator.

Regarding the means for suppression of pass-band ripple in bulk acoustic wave filters the object is solved by a BAW resonator that comprises at least a bottom electrode, a piezoelectric layer and a top electrode, a basic substrate and means for absorbing or scattering spurious modes which are selected from the group of
roughened rear side of the substrate,
on rear side of substrate disposed absorbing layer and/or
on front side of substrate disposed absorbing layer.

These means prevent the basic substrate from getting in vibrations as one surface of the basic substrate does not stay smooth but becomes uneven respectively contacts a layer which comprises small cavities. According to one aspect of the invention the surface is made uneven by roughening the basic substrate. According to other aspects of the invention the surface is made uneven in an indirect way by disposing a rear side or a front side absorbing layer which has a porous structure. Anyway, as the surface of the basic substrates is made uneven, either in a direct way or in an indirect way, acoustic waves impacting the surface are partially scattered.

According to one embodiment the rear side of the basic substrate is roughened by a chemical treatment like etching or by a mechanical treatment like blasting.

According to another embodiment the rear side absorbing layer or the front side absorbing layer are/is selected from the group of glue such as epoxy glue, elasticoviscous materials such as polyimide, rubber, plastic materials, porous media like aerogel or xerogel or porous thin films. The advantage of epoxy glue is its ultimate tensile strength and that it is stress free once it is hardened. The advantage of elasticoviscous materials is the high thermostability. The advantage of rubber is its limberness which only reflects a small part of sound. The advantage of porous media is that the curved surface only reflects parts of impact acoustic waves.

Regarding the bulk acoustic wave filter the object is solved by at least two bulk acoustic wave resonators which comprise means for suppression of pass-band ripple in a ladder or in a lattice type configuration that are alternatively
a roughened rear side of a basic substrate,
an absorbing layer disposed on the rear side of the substrate and/or
an absorbing layer disposed on the front side of the substrate below a Bragg reflector.

This BAW filter has an improved band-pass filter behavior as the means for suppression are chosen in such a way that spurious modes are absorbed or scattered.

According to one embodiment of the invention the top electrode is made of a metal material such as aluminum (Al). According to another embodiment of the invention the piezoelectric layer is made of aluminum nitride (AlN), zinc oxide (ZnO) or lead zirconate titanate (PZT). According to a further embodiment the bottom electrode is made of a metal material such as Molybdenum (Mo), Platinum (Pt) or Tungsten (W).

Regarding the method the invention is solved by a method for manufacturing a bulk acoustic wave resonator which comprises the steps of
providing a silicon chip or dice,
disposing the top electrode on the silicon chip or dice,
disposing the piezoelectric layer,
disposing the bottom electrode,
disposing the Bragg reflector,
disposing the front side absorbing layer,
disposing the basic substrate,
removing the silicon dice or chip.

This method uses the advantages of the substrate/wafer transfer process.

The invention will be explained by means of example wherein

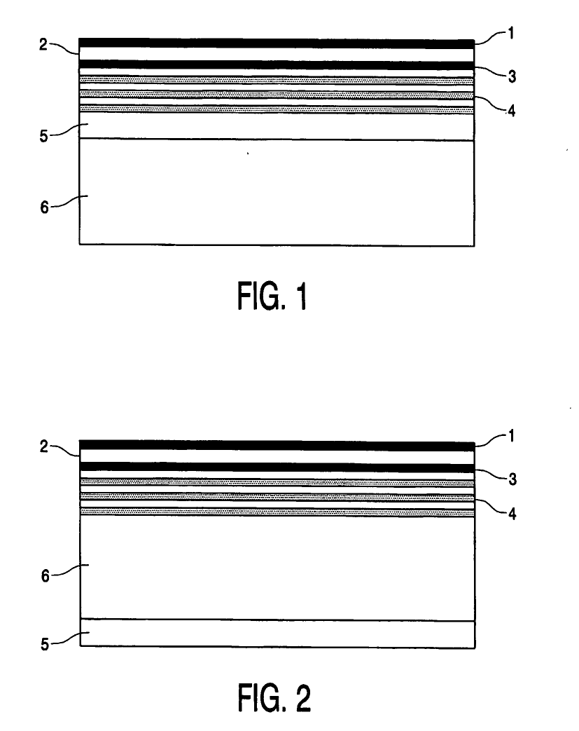

FIG. 1 shows a BAW resonator with a roughened rear side of the substrate,

FIG. 2 shows an absorbing layer that is disposed onto the rear side of the substrate,

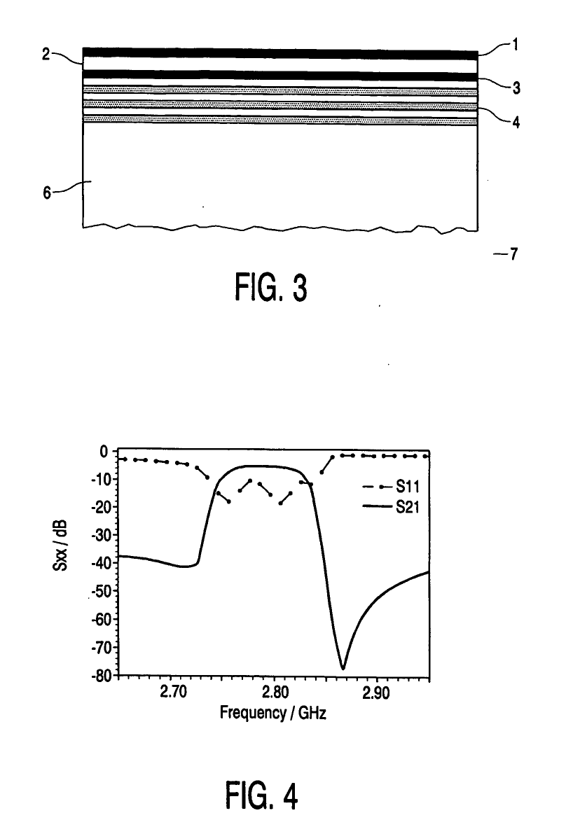

FIG. 3 shows an absorbing layer that is disposed onto the front side of the substrate and below a Bragg reflector,

FIG. 4 shows a bulk resonator's frequency response of a 2.79 GHz BAW filter which comprises some of the above mentioned means for suppression of the band-pass ripple.

FIG. 1 shows a BAW resonator with a roughened read side of a substrate 5 that is building the basis. The resonator comprises a top electrode 1 disposed onto a piezoelectric layer 2 which is arranged on a bottom electrode 3 with the top and the bottom electrodes 1, 3 and encasing the piezoelectric layer 2 in a sandwich like way.

In order to de-couple the sandwich structure from the basic substrate 5 a Bragg reflector 4 is arranged in between. The basic substrate 5 has a front side aligned towards the arrangement of the electrodes and a rear side aligned to the opposed side. The Bragg reflector 4 is built of alternate high and low acoustic impedance material. According to this embodiment the rear side of the substrate 5 is roughened in order to scatter the standing wave. The rear side of the substrate 5, which is for example made of a glass substrate or a semiconductor substrate, can be roughened for example by means of etching or blasting.

FIG. 2 shows a BAW resonator with an absorbing layer 6 that is disposed onto the rear side of the substrate 5. The rear side absorbing layer 6 is made of a glue that has a high acoustic absorption capability such as epoxy glue or silicon rubber. Because of its scattering behavior the rear side absorbing layer 6 avoids acoustic waves from penetrating into the substrate 5.

FIG. 3 shows a BAW resonator with an absorbing layer 7 that is disposed onto the front side of the substrate 5 and below the Bragg reflector 4. This absorbing layer is made of a glue with a high acoustic absorption like epoxy glue or silicon rubber. In a preferred embodiment this resonator with a front side absorbing layer 7 is manufactured by a process called substrate/wafer transfer. The manufacturing of this preferred embodiment of a bulk resonator comprises the following steps
providing a silicon chip or dice,
disposing the top electrode made of a metal material like aluminum (Al),
disposing a piezoelectric layer like aluminum nitride (AlN) or zinc oxide (ZnO),
disposing a bottom electrode made of a metal material like Platinum (Pt), Molybdenum (Mo) or Tungsten (W),
disposing a Bragg reflector,
disposing an absorbing layer like epoxy glue to the front side of the substrate,
disposing a substrate like for example glass substrate,
removing the silicon dice.

FIG. 4 shows a diagram with the response of a BAW resonator filter curve in which the bass-band ripple is reduced by adding an absorbing layer 7 on top of the substrate 5. The curve is detected by a frequency analyzer. In this example substrate 5 is a glass substrate and absorbing layer 7 was an epoxy glue. A Bragg reflector 4 consists of alternate λ/4 layers of SiO₂ and Ta₂O₅. On top of the Bragg reflector 4 the bottom electrode 3 made of platinum (Pt) and a piezoelectric film (2) are stacked. As top electrode 1 aluminum is used. As can be seen, the pass-band of curve S 21 (transmission) in the region of 2.79 GHz is free of any ripple. This is due to the use of an absorbing layer underneath the Bragg reflector on top of the glass substrate. The dash-dot curve shows the reflection S 11 of the filter. The absorbing layer is epoxy glue. Other materials which can be used as acoustic absorber are elasticoviscous materials such as polyimide, all kinds of glue, rubber, plastic materials, porous media like aerogel or xerogel and porous thin films in which either acoustic absorption mechanisms are dominant or acoustic scattering occurs.

The features described in the description, the drawing and the claims disclosing the invention may be essential for the inventions, considered alone or in combination.

1. A bulk acoustic wave (BAW) resonator comprising at least a bottom electrode (3), a piezoelectric layer (2) and a top electrode (1), a basic substrate (5) and means for absorbing or scattering spurious modes, characterized in that the means for absorbing or scattering spurious modes are selected from the group of
roughened rear side of the basic substrate (5),
on rear side of substrate (5) disposed absorbing layer (6) and/or
on front side of substrate (5) disposed absorbing layer (7).

2. A BAW resonator as claimed in claim 1, characterized in that the rear side of the basic substrate (5) is roughened by means of etching or blasting.

3. A bulk resonator as claimed in claim 1, characterized in that the rear side absorbing layer (6) and/or the front side absorbing layer (7) are/is selected from the group of glue such as epoxy glue, elasticoviscous materials such as polyimide, rubber, silicon rubber, plastic materials, porous media like aerogel or xerogel or porous thin films.

4. A bulk acoustic wave filter comprising at least two bulk acoustic wave resonators which comprise means for suppression of pass-band ripple in a ladder or in a lattice type configuration characterized in that the resonator's means for suppression of pass-band ripple are alternatively
a roughened rear side of the basic substrate (5),
an absorbing layer (6) disposed on the rear side of the substrate (5) and/or
an absorbing layer (7) disposed on the front side of the substrate (5) and below a Bragg reflector (4).

5. A bulk resonator as defined in one of the preceding claims, characterized in that the top electrode is made of a metal material such as aluminum (Al) and/or
the piezoelectric layer is made of aluminum nitride (AlN), zinc oxide (ZnO) or lead zirconate titanate (PZT) and/or
the bottom electrode is made of a metal material such as Molybdenum (Mo), Platinum (Pt) or Tungsten (W).

6. Method for manufacturing a bulk acoustic wave resonator comprising the steps of
providing a silicon chip or dice,
disposing the top electrode (1) on the silicon dice,
disposing the piezoelectric layer (2),
disposing the bottom electrode (3),
disposing the Bragg reflector (4),
disposing the front side absorbing layer (7),
disposing the basic substrate (5),
removing the silicon dice.
